(19) United States
(12) Patent Application Publication
(10) Pub. No.: US 2014/0179064 A1
(43) Pub. Date: Jun. 26, 2014

(54) METHOD FOR FABRICATING A PACKAGE-IN-PACKAGE FOR HIGH HEAT DISSIPATION

(71) Applicant: TEXAS INSTRUMENTS INCORPORATED, Dallas, TX (US)

(72) Inventors: Matthew D. Romig, Richardson, TX (US); Marie-Solange Milleron, Richardson, TX (US)

(73) Assignee: TEXAS INSTRUMENTS INCORPORATED, Dallas, TX (US)

(21) Appl. No.: 14/189,404

(22) Filed: Feb. 25, 2014

Related U.S. Application Data
(62) Division of application No. 13/488,054, filed on Jun. 4, 2012.

(51) Int. Cl. H01L 21/56; H01L 23/00

(52) U.S. Cl. CPC H01L 21/561; H01L 24/95
USPC 438/118; 438/122

(57) ABSTRACT

A method for fabricating a semiconductor system starts with providing a first component including a first semiconductor chip attached to a pad of a first metal leadframe made of a first metal sheet of high thermal conductivity. A second component including a second semiconductor chip attached to a pad of a second metal leadframe made of a second metal sheet wire-bondable on both surfaces is provided. The second component is encapsulated in a polymeric housing leaving un-encapsulated the lead surfaces facing away from the second chip. The polymeric housing of the second component is attached to the first chip using a layer of low thermal conductivity, whereby the un-encapsulated lead surfaces face away from the first chip. Bonding wires are connected to the un-encapsulated surfaces of the second component leads to the leads of the first component.

### CROSS-REFERENCE TO RELATED APPLICATIONS

This application is a Divisional and claims priority to U.S. patent application Ser. No. 13/488,054, filed on Jun. 4, 2012. Said application is herein incorporated by reference.

### FIELD

The present invention is related in general to the field of semiconductor devices and processes, and more specifically to an encapsulated device including another encapsulated device, both devices assembled for high heat dissipation using leadframes and wire bonds.

### DESCRIPTION OF RELATED ART

The long-term trends in semiconductor packaging are efforts to shrink the package outline so that the package consumes less area and less height when it is mounted onto the circuit board, and to reach these goals with minimum cost (both material and manufacturing cost). Recently, other requirements were added to this list, namely the need to have a high number of input/output terminals, and the need to design packages so that stacking of chips and/or packages becomes an option to increase functional density and reduce device thickness.

A successful strategy for stacking chips and packages can shorten the time-to-market of innovative products, which utilize available chips of various capabilities (such as processors and memory chips) and thus does not have to wait for a redesign of chips.

Recent applications especially for hand-held wireless equipments, combined with ambitious requirements for data volume and high processing speed, place new, stringent constraints on the size and volume of semiconductor components used for these applications. Consequently, the market place is renewing a push to shrink semiconductor devices both in two and in three dimensions, and this miniaturization effort includes packaging strategies for semiconductor devices as well as electronic systems.

The wide variety of products collectively called Micro-Electro-Mechanical devices (MEMS) are small, low weight devices on the micrometer to millimeter scale, which may have mechanically moving parts and often movable electrical power supplies and controls, or they may have parts sensitive to thermal, acoustic, or optical energy. MEMS have been developed to sense mechanical, thermal, chemical, radiant, magnetic, and biological quantities and inputs, and produce signals as outputs. Examples are pressure sensors and inertial sensors coupled with the integrated electronic circuit of the chip. Because of the moving and sensitive parts, MEMS have a need for physical, atmospheric, and sometimes thermal protection. Consequently, MEMS are placed on a substrate and have to be surrounded by a housing or package, which may have to shield the MEMS against ambient and electrical disturbances and against unwanted stress and thermal onrush.

Many schemes for integrating chips of the processor, memory, and logic ASIC families in a single package have been attempted. One recent advanced scheme combines flip-chip and wire-bond interconnections in a 3-D package that vertically stacks a pre-tested chip, such as a memory chip, in a land-grid array format and bare chips into one flip-chip ball grid array package assembled on a multi-metal-level plastic or ceramic substrate. Housings for such systems are frequently referred to as flip-chip package-in-package (fcPIP).

### SUMMARY

Applicants analyzed known package-in-package arrangements for semiconductor chips with regard to their suitability for stacking a MEMS device, such as an acoustic resonator, together with other chips, especially heat-generating integrated circuits (ICs), inside the package. The analysis showed that available packages offer only marginal solutions due to unacceptably poor thermal characteristics for heat dissipation from the heat-generating IC and for thermal shielding of the MEMS stacked on top of the larger IC. In addition, available PIP structures are too expensive for mass market penetration of products including MEMS.

Applicants solved the problem of package thermal performance and suitability for a pre-packaged component such as a MEMS, when they discovered a two-prong approach, which furthermore is low-cost. As the first step, the thermal energy generated by the large-area IC is removed by a sheet of metal with high thermal conductivity, such as copper. The thermal energy can dissipate from the metal sheet into an attached external heat sink. A low-cost embodiment is the chip pad of a solid copper leadframe. As the second step, a layer of low thermal conductivity is inserted between the IC and the pre-packaged component, such as a MEMS. A preferred approach includes an adhesive polymeric layer free of metallic fillers, which has a thickness sufficient to block the majority of the thermal energy from propagating from the IC to the pre-packaged component.

The pre-packaged component has the silicon chip attached to the pad of a leadframe made of a metal sheet wire-bondable on both surfaces; the chip is connected by bonding wires to one surface of the leadframe leads. Chip and bonding wires are encapsulated in a polymeric housing, which leaves the opposite surface of the leads un-encapsulated. This opposite surface of the leads is available for wire bonding the leads to the first metal leadframe, since the adhesive layer of low thermal conductivity is attached to the polymeric housing.

In order to electrically connect the pre-packaged component to the IC and its leadframe, the preferred approach employs wire bonding. The preferred wire metal is copper. Consequently, the un-encapsulated surface of the component leadframe has to be bondable to copper wires; a preferred surface preparation includes a sequence of nickel, palladium and gold layers. Insides the component, the frequently preferred wire bonding includes gold.

### BRIEF DESCRIPTION OF THE DRAWINGS

FIG. 1 shows a cross section of an embodiment including a first chip attached and wire bonded to a first sheet of metal of high thermal conductivity, and the package encapsulating a second chip attached to the first chip by a layer of low thermal conductivity. Both surfaces of the leadframe of the second chip are bondable.

FIG. 2 illustrates a top view of the embodiment of FIG. 1 with the packaging compound assumed to be transparent.

### DETAILED DESCRIPTION OF THE PREFERRED EMBODIMENTS

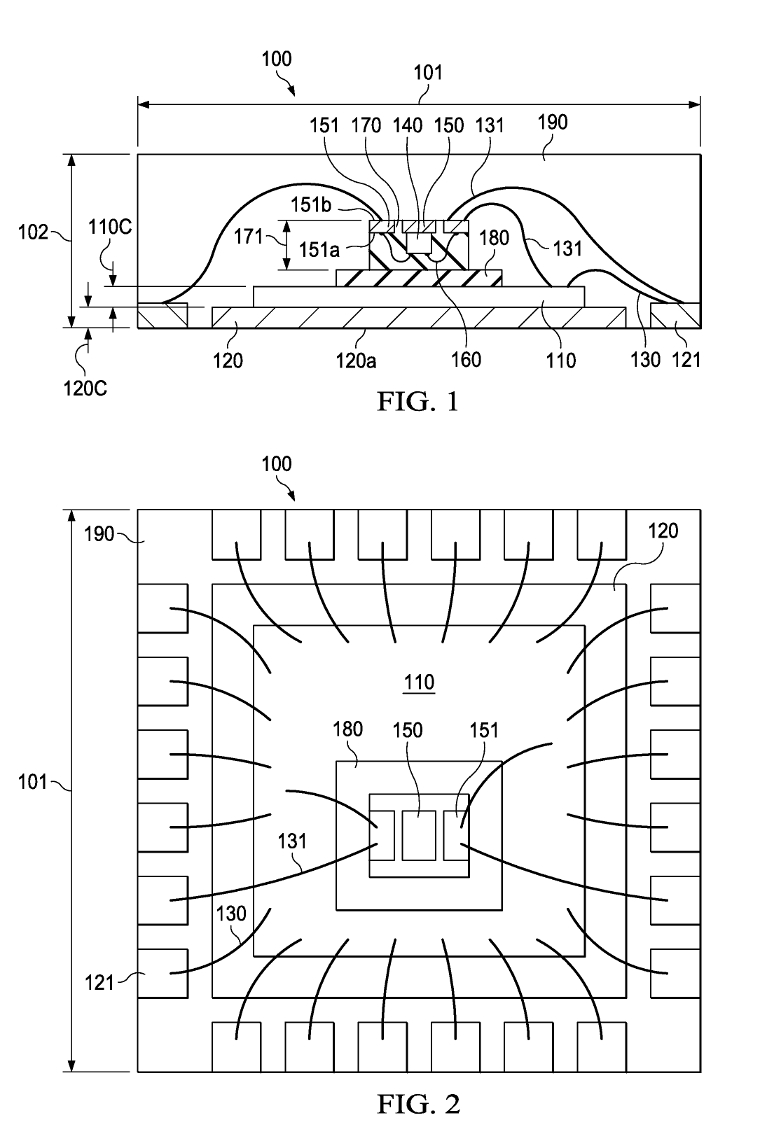

FIG. 1 shows as an exemplary embodiment a packaged semiconductor system generally designated 100, which incorporates a packaged second component within the package of the first component. Such systems are frequently referred to as package-in-package (PIP) systems. Dependent on the function and size of the semiconductor chips of the components, the dimensions of system 100 may ray over a wide range of dimensions. As examples, lateral dimensions 101 may be between about 4 and 10 mm, and height 102 may be between about 1.0 and 1.5 mm.

An exemplary first component of system 100 includes a heat-generating first semiconductor chip 110, which may be a microprocessor in combination with a memory element. These chips 110 are of large geometrical size and operate at high speed, which generates high amounts of thermal energy in full operation. Thickness 110c of chip 110 may be in the range from about 125 to 200 μm. Chip 110 is attached by a thin layer of adhesive or solder to a pad 120 of a first metal of high thermal conductivity, such as copper (401 W m⁻¹ K⁻¹), silver (429 W m⁻¹ K⁻¹), aluminum (237 W m⁻¹ K⁻¹) and alloys of these metals. Thickness 120c of pad 120 may be in the range from about 150 to 200 μm.

For reasons of practical manufacturability, pad 120 is preferably the pad of a leadframe made of a sheet of first metal. Based on this concept, pad 120 and leads 121 can be simultaneously stamped or etched from a solid starting sheet of first metal of high thermal conductivity. After the attachment of first chip 110 on pad 120, the terminals of chip 110 are electrically connected to leads 121 of the leadframe by bonding wires 130. Preferably, wires 130 include copper and leads 121 are bondable to copper wires. Leads 121 have a bondable surface onto which wires 130 are attached. Pad 120 preferably has an outer surface 120a for easy contact to an external heat sink; for instance, surface 120a may be solderable.

As displayed in FIG. 1, system 100 includes a second component, which may for instance be a micro-electro-mechanical system (MEMS) in a package of the Quad Flat No-Lead (QFN) or Small Outline No-Lead (SON) families. The second component includes a second semiconductor chip 140 of a geometrical size, which for many device families is small compared to the geometrical size of first chip 110. Chip 140 may, however, have the same height between about 125 and 200 μm as chip 110. If second component is a MEMS, chip 140 may be a vibration sensor or a temperature-sensitive chip.

Chip 140 is attached to the pad 150 of a leadframe made of a second metal sheet. The base metal of the second sheet may be selected from a group consisting of copper, aluminum, iron-nickel compounds, and Kovar™ as long as both sheet surfaces are bondable. The second metal sheet includes a pad 150 and a plurality of leads 151. The second metal sheet is bondable on both surfaces; consequently, leads 151 are bondable on both surfaces 151a and 151b. As an exemplary method for bondability, the second sheet may have one layer of bondable metal plated on both sheet surfaces. Alternatively, second sheet may have a sequence of layers such as nickel, palladium, and gold plated on both surfaces.

The terminals of chip 140 are connected by bonding wires 160 to one surface 151a of leads 151. For small chips 140, especially for MEMS, wires 160 may be made of gold; alternatively, copper is well accepted. Chip 140, bonding wires 160 and lead surface 151a are encapsulated in a housing 170 made of a polymeric compound, whereby the opposite surface 151b of the leads remains un-encapsulated. As a preferred example, the polymeric compound may be an epoxy-based molding compound. The thickness 171 of the encapsulated second component, including the second leadframe thickness, is preferably in the range from about 0.3 to 0.5 mm; other embodiments may have thinner or thicker packages.

As shown in FIG. 1, housing 170 of the second component is attached to first chip 110 by a layer 180 of low thermal conductivity and the ability to withstand temperatures customarily involved in wire bonding, solder reflow, and curing of molding compounds. The attachment is performed so that the un-encapsulated lead surface 151b of the second component faces away from first chip 110. As an example for attachment layer 180, it may be made of an adhesive polymeric compound without conductive fillers. The thermal conductivity of these compounds is approximately three orders of magnitude smaller than the thermal conductivity of metals and may be in the range of 0.23 W m⁻¹ K⁻¹. Alternative materials of low thermal conductivity, expressed in 10⁻³ W m⁻¹ K⁻¹, may include polystyrene (140), teflon (230), foam plastics such as foam polyurethane (15 to 60), and foam glass (50 to 70). Consequently, layer 180 acts at an exemplary thickness in the range from about 10 to 30 μm as a thermal barrier between the second component—and its second chip 140—and first chip 110, which is frequently an IC operating at high speed and thus generating elevated temperatures.

The bondable and un-encapsulated lead surfaces 151b of the second component are bonded by wires 131 to leads 121 of the first leadframe or to terminals of first chip 110. Preferably, wires 131 include copper and the surface 151b of the leads is bondable to copper wires. As a consequence of the wire connections 131 of the second component to the leads and the chip of the first component, in conjunction with the attachment of compound 170 to chip 110, the second component is integrated with the first component, forming a so-called package-in-package PIP.

As FIG. 1 shows, the integrated components are packaged by plastic compound 190, preferably a molding compound, which leaves surface 120a of the first metal pad exposed so that it can operate to dissipate thermal energy into an external heat sink. In this fashion, the heat-generating IC chip 120 can be effectively cooled. Allowing a compound thickness of about 250 μm or more in order to reliably cover the arches of bonding wires 131, the total height 102 of system 100 will fall into the range from about 1.0 to 1.5 mm.

FIG. 2 illustrates a top view of exemplary packaged system 100, wherein for clarity reasons the encapsulating compound 190 of the package is considered transparent. With a QFN/SON-type outline, the package has square shape (lateral dimension 101) and 24 pins 121. First semiconductor chip 110 is attached to pad 120 of the leadframe of the first metal sheet of high thermal conductivity, and connected by bonding wires 130 to pins 121. The top view of FIG. 2 further shows the second component attached to chip 110 by layer 180 of low thermal conductivity. Leads 151 of the second component leadframe are visible and connected by bonding wires 131 to leads 121 and chip 110. On the other hand, the second semiconductor chip is hidden by pad 150 of the leadframe of the second metal sheet.

Another embodiment of the invention is a method for fabricating a semiconductor system including at least two components. The method starts by providing a first component, which includes a first semiconductor chip 110 attached to the pad 120 of a leadframe made of a first metal sheet of high thermal conductivity. Copper is a preferred choice for the leadframe; other choices may include copper alloys of high thermal conductivity.

Next, a second component is provided, which includes a second semiconductor chip 140 attached to the pad 150 of a leadframe made of a second metal sheet wire-bondable on both surfaces. The bondability to metal wires can be created by a thin surface layer of gold or a sequence of nickel, palladium, and gold layers. Second chip 140 is wire bonded to the surface of leadframe leads, which faces chip 140. In addition, chip 140 and wires 160 are encapsulated in a polymeric housing 170, which leaves un-encapsulated the lead surfaces 151b facing away from second chip (140).

For small chips 140, or for MEMS chips, it is advantageous to assemble the large quantity of chips obtained from a whole semiconductor wafer in a consecutive series of batch process steps and keep the assembled units in inventory until they are needed as second components for the assembly into a system.

For the assembly into a system, the polymeric housing 170 of a selected second component is attached to first chip 110 using a layer 180 of low thermal conductivity; in this step, the lead surfaces un-encapsulated in compound 170 face away from first chip 110. As mentioned above, the material of low thermal conductivity is selected by manufacturability and the ability to withstand temperatures customarily involved in wire bonding, solder reflow, and curing of molding compounds. The thermal conductivity values listed above are in the range of 0.23 W m⁻¹ K⁻¹ and include a wide range of polymeric compounds. Layer 180 operates as a thermal barrier between the heat produced by chip 110 in operation and the heat-sensitive chip 140.

In the next process step, bonding wires 131 are used to connect the un-encapsulated surfaces 151b of leads 151 of the second component to the leads 121 of the first component. In additional bonding steps, wires 130 connect chip 110 to leads 121 of the leadframe of the first component.

In the final assembly step, the first component together with the attached second component are encapsulated in polymeric molding compound 190, whereby both components are integrated into packaged system 100.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies not only to integrated circuits as chips of the first component, but also to systems with any type of semiconductor chip.

As another example, the encapsulated second component may not only be a MEMS device, but may include any chip of relatively small size compared to the chip of the first component.

As yet another example, structure and method of the invention, especially with regard to thermal aspects, apply to components, which may partially use solder attachment as replacement of wire bonding.

It is therefore intended that the appended claims encompass any such modifications or embodiments.

We claim:

1-8. (canceled)

9. A method for fabricating a semiconductor system comprising:
providing a first component including a first semiconductor chip attached to a pad of a first metal leadframe made of a first metal sheet of high thermal conductivity;
providing a second component including a second semiconductor chip attached to a pad of a second metal leadframe made of a second metal sheet wire-bondable on both surfaces, the second component encapsulated in a polymeric housing leaving un-encapsulated the lead surfaces facing away from the second chip;
attaching the polymeric housing of the second component to the first chip using a layer of low thermal conductivity, whereby the unencapsulated lead surfaces face away from the first chip; and
connecting with a plurality of bonding wires the un-encapsulated surfaces of the second component leads to the leads of the first component.

10. The method of claim 9 further including, after connecting, connecting the first chip to leads of the first leadframe using bonding wires.

11. The method of claim 9 wherein the second component further includes bonding wires connecting the second chip to leadframe leads at the surface facing the second chip.

12. The method of claim 11 further including encapsulating the first component together with the attached second component in a polymeric molding compound, whereby both components are integrated into a packaged system.

13. The method of claim 9 wherein the first metal sheet of high thermal conductivity includes copper.

14. The method of claim 9 wherein the layer of low thermal conductivity is an adhesive polymeric compound free of metallic fillers.
